(19) United States
(12) Patent Application Publication
(10) Pub. No.: US 2024/0288504 A1
(43) Pub. Date: Aug. 29, 2024

(54) RAPID MAPPING OF ELECTROCHEMICAL PROCESSES IN ENERGY CONVERSION DEVICES

(71) Applicant: Colorado School of Mines, Golden, CO (US)

(72) Inventors: Ryan P. O'Hayre, Golden, CO (US); Jake Dickey Huang, Golden, CO (US)

(21) Appl. No.: 18/584,766

(22) Filed: Feb. 22, 2024

Related U.S. Application Data
(60) Provisional application No. 63/486,804, filed on Feb. 24, 2023.

(51) Int. Cl. G01R 31/389; G01R 31/367; G01R 31/392

(52) U.S. Cl. CPC G01R 31/389; G01R 31/367; G01R 31/392

(57) ABSTRACT

An integrated measurement and analysis technique that greatly reduces the time required to measure and analyze electrochemical activity while maintaining high resolution. The order-of-magnitude increase in speed is potentially transformative for electrochemical characterization: it enables new modes of investigation that produce comprehensive images of electrochemical activity, rather than isolated fragments of information. The insight derived from the integrated measurement and analysis techniques of the present disclosure should be invaluable for stimulating innovations towards next-generation energy technologies.

### CROSS-REFERENCE TO RELATED APPLICATIONS

The present application claims the priority to U.S. Provisional Patent Application Ser. No. 63/486,804, filed Feb. 24, 2023, entitled RAPID MAPPING OF ELECTROCHEMICAL PROCESSES IN ENERGY CONVERSION DEVICES, and is related to International Application No. PCT/US24/16824, filed Feb. 22, 2024, entitled RAPID MAPPING OF ELECTROCHEMICAL PROCESSES IN ENERGY CONVERSION DEVICES, a copy of each of which is hereby incorporated by reference as if fully set forth herein in its entirety.

### GOVERNMENT INTEREST

This invention was made with government support awarded by the Department of Energy (DOE) under Award Number DE-SC0023450, and the Army Research Office (ARO) under Award Number W911NF-22-1-0273. The U.S. Government may have certain rights in the invention.

### FIELD OF THE DISCLOSURE

The present disclosure is generally directed to systems, methods, and devices for mapping electrochemical processes in energy conversion devices.

### BACKGROUND

Electrochemical energy conversion devices like batteries, fuel cells, and electrolyzers are expected to play a crucial role in the transition to sustainable energy infrastructure. A clear understanding of their properties, underlying physical processes, and limiting factors is needed to facilitate improvements to existing materials and technologies. However, existing in-situ electrochemical characterization techniques are time-consuming and difficult to interpret.

### SUMMARY

Electrochemical energy conversion devices like batteries, fuel cells, and electrolyzers are expected to play a crucial role in the transition to sustainable energy infrastructure. A clear understanding of their properties, underlying physical processes, and limiting factors is needed to facilitate improvements to existing materials and technologies. However, existing in-situ electrochemical characterization techniques are time-consuming and difficult to interpret. Embodiments of the present disclosure provide an integrated measurement and analysis technique that greatly reduces the time required to measure and analyze electrochemical activity while maintaining high resolution. The order-of-magnitude increase in speed is potentially transformative for electrochemical characterization: it enables new modes of investigation that produce comprehensive images of electrochemical activity, rather than isolated fragments of information. The insight derived from this technique should be invaluable for stimulating innovations towards next-generation energy technologies.

Electrochemical impedance spectroscopy is ubiquitously applied to identify the physicochemical processes that govern the performance of energy conversion devices. However, the complexity of observed impedance phenomena often obfuscates interpretation, necessitating numerous time-consuming measurements to obtain meaningful insight. Embodiments of the present disclosure provide a technique to accelerate electrochemical characterization by utilizing rapid measurements in both the time and frequency domains. This method provides excellent resolution across a broad range of timescales while decreasing measurement time by more than an order of magnitude. Embodiments of the present disclosure can be applied to quickly construct detailed electrochemical maps of energy conversion devices across multiple measurement condition dimensions, revealing physicochemical relationships that are hidden in sparse conventional datasets. In addition, rapid time-resolved measurements capture transient states that further elucidate underlying physical mechanisms. These techniques of embodiments of the disclosure are practical and powerful tools that can provide previously inaccessible insight.

Embodiments of the present disclosure provide a system for mapping electrochemical devices, the system comprising: a processor and a memory device coupled with the processor, wherein the memory device comprises data stored thereon that, when processed by the processor, enables the processor to: generate a time-domain current signal and/or a frequency-domain current signal; send the time-domain current signal and/or the frequency-domain current signal to a measurement instrument; receive raw time-domain data and/or raw frequency-domain data from the measurement instrument; process the raw time-domain data and/or the raw frequency-domain data with a model to determine a distribution of relaxation times (DRT) that captures resistive-capacitive (RC) behavior and a distribution of phasances (DOP) that captures constant-phase behavior; mitigate time-domain perturbations with a Gaussian Process filter to improve the accuracy of model results; and output a DRT-DOP model that provides an interpretable, separable representation of electrochemical processes and an estimate of the electrochemical impedance spectrum.

Aspects of the above system include wherein the processor is further enabled to perform a measurement in both time and frequency domains. By performing a measurement as described herein, a representation of electrochemical processes and an estimate of the electrochemical impedance spectrum of an energy conversion device can be completed ten to one hundred times faster than conventional measurement methods. Aspects of the above system include wherein the processor is further enabled to construct electrochemical maps of energy conversion devices. Aspects of the above system include wherein the DRT-DOP model provides resolution equivalent to or greater than that of conventional methods across a broad range of time scales. Aspects of the above system include wherein measurement time as compared to conventional measurement devices is decreased. For example, in some embodiments, measurement time can be decreased such that measurement takes around 40 seconds and is ninety times faster than conventional methods. Aspects of the above system include wherein the timescale-resolved description is across multiple measurement condition dimensions. Aspects of the above system include wherein the processor is further enabled to capture transient states.

Embodiments include a device, comprising a processor to perform: generating a time-domain current signal and/or a frequency-domain current signal; sending the time-domain current signal and/or the frequency-domain current signal to a measurement instrument; receiving raw time-domain data and/or raw frequency-domain data from the measurement instrument; processing the raw time-domain data and/or the raw frequency-domain data with a model to determine a DRT that captures RC behavior and a DOP that captures constant-phase behavior; mitigating time-domain perturbations with a Gaussian Process filter to improve the accuracy of model results; and outputting a DRT-DOP model that provides an interpretable, separable representation of electrochemical processes and a robust estimate of the electrochemical impedance spectrum.

Aspects of the above device include wherein the processor is further enabled to perform a rapid measurement in both time and frequency domains. Aspects of the above device include wherein the processor is further enabled to construct detailed electrochemical maps of energy conversion devices. The electrochemical maps of energy conversion devices constructed using systems and methods as described herein include a greater amount of data as compared to conventional methods of characterizing and analyzing energy conversion devices. The amount of data included in the electrochemical maps of energy conversion devices constructed using systems and methods as described herein is of a higher resolution as compared to conventional methods of characterizing and analyzing energy conversion devices. Aspects of the above device include wherein the DRT-DOP model provides high resolution across a broad range of time scales as compared to conventional methods of characterizing energy conversion devices. Aspects of the above device include wherein measurement time as compared to conventional measurement devices is decreased. Aspects of the above device include wherein the timescale-resolved description is across multiple measurement condition dimensions. Aspects of the above device include wherein the processor is further enabled to capture transient states.

Embodiments include a method of measuring an electrochemical device, the method comprising: generating a time-domain current signal and/or a frequency-domain current signal; sending the time-domain current signal and/or the frequency-domain current signal to a measurement instrument; receiving raw time-domain data and/or raw frequency-domain data from the measurement instrument; processing the raw time-domain data and/or the raw frequency-domain data with a model to determine a DRT that captures RC behavior and a DOP that captures constant-phase behavior; mitigating time-domain perturbations with a Gaussian Process filter to improve the accuracy of model results; and outputting a DRT-DOP model that provides an interpretable, separable representation of electrochemical processes and a robust estimate of the electrochemical impedance spectrum.

Aspects of the above method include performing a rapid measurement in both time and frequency domains. Aspects of the above method include constructing detailed electrochemical maps of energy conversion devices. Aspects of the above method include wherein the DRT-DOP model provides high resolution across a broad range of time scales. Aspects of the above method include wherein measurement time as compared to conventional measurement devices is decreased. Aspects of the above method include wherein the description is across multiple measurement condition dimensions.

Embodiments include a device, comprising a processor to perform: receiving raw time-domain data and raw frequency-domain data associated with an energy-conversion device; combining the raw time-domain data and the raw frequency-domain data; transforming the combined raw time-domain data and frequency-domain data using a DRT-DOP model; and generating, based on the DRT-DOP model, an electrochemical impedance spectrum of the energy-conversion device

### BRIEF DESCRIPTION OF THE DRAWINGS

The accompanying drawings are incorporated into and form a part of the specification to illustrate several examples of the present disclosure. These drawings, together with the description, explain the principles of the disclosure. The drawings simply illustrate preferred and alternative examples of how the disclosure can be made and used and are not to be construed as limiting the disclosure to only the illustrated and described examples. Further features and advantages will become apparent from the following, more detailed, description of the various aspects, embodiments, and configurations of the disclosure, as illustrated by the drawings referenced below.

The present disclosure is described in conjunction with the appended figures, which are not necessarily drawn to scale:

FIG. 1 is a block diagram of a system in accordance with one or more of the embodiments described herein;

FIG. 2 is a block diagram of a computing system in accordance with one or more of the embodiments described herein;

FIGS. 3-8 are graphs in accordance with one or more of the embodiments described herein;

FIG. 9 is a flowchart of a method in accordance with one or more of the embodiments described herein;

FIGS. 10A and 10B illustrate results of a hybrid measurement in accordance with one or more of the embodiments described herein in comparison to conventional EIS measurement; and

FIGS. 11A-F illustrate a process of mapping impedance of an energy-conversion device in accordance with one or more of the embodiments described herein.

### DETAILED DESCRIPTION

Before any embodiments of the disclosure are explained in detail, it is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, the present disclosure may use examples to illustrate one or more aspects thereof unless explicitly stated otherwise, the use or listing of one or more examples (which may be denoted by “for example,” “by way of example,” “e.g.,” “such as,” or similar language) is not intended to and does not limit the scope of the present disclosure.

The details of one or more aspects of the disclosure are set forth in the accompanying drawings and the description below. Other features, objects, and advantages of the techniques described in this disclosure will be apparent from the description and drawings, and from the claims.

The phrases “at least one,” “one or more,” and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

Numerous additional features and advantages are described herein and will be apparent to those skilled in the art upon consideration of the following Detailed Description and in view of the figures.

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

It will be appreciated from the following description, and for reasons of computational efficiency, that the components of the system can be arranged at any appropriate location within a distributed network of components without impacting the operation of the system.

Further, it should be appreciated that the various links connecting the elements can be wired, traces, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a Printed Circuit Board (PCB), or the like.

The terms “determine,” “calculate,” and “compute,” and variations thereof, as used herein, are used interchangeably, and include any appropriate type of methodology, process, operation, or technique.

Various aspects of the present disclosure will be described herein with reference to drawings that may be schematic illustrations of idealized configurations.

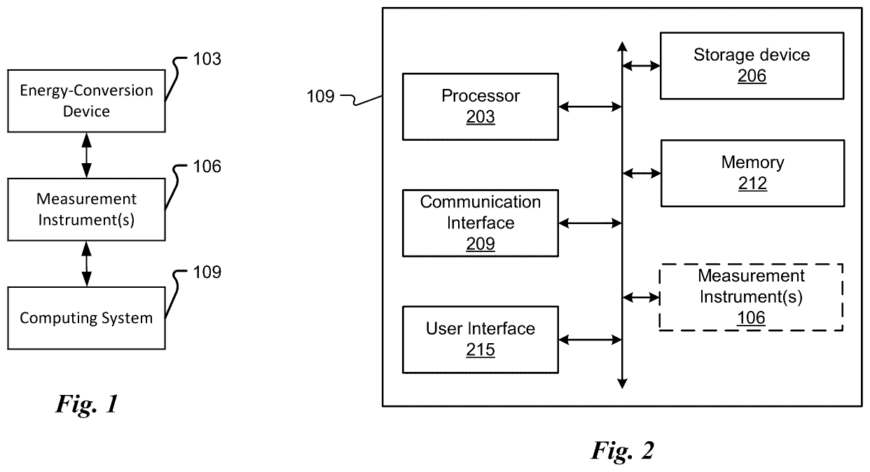

As illustrated in FIG. 1, the systems and methods described herein may be performed by a computing system 109 comprising and/or communicating with one or more measurement instruments 106 to assess state-of-charge (SOC), health, and/or other metrics associated with an energy conversion device 103.

An energy conversion device 103 as described herein may be an electrochemical energy conversion device. The systems and methods described herein may be implemented to determine metrics associated with a wide array of energy-conversion devices 103 including, but not limited to, fuel cells, batteries, electrolyzers, supercapacitors, photoelectrochemical devices, and/or other devices capable of producing energy from a fuel.

Electrochemical energy conversion devices such as batteries, fuel cells, and electrolyzers play a crucial role in the transition to sustainable energy infrastructure. A clear understanding of the properties, underlying physical processes, and limiting factors of such devices will facilitate technological improvements. However, existing in-situ electrochemical characterization techniques are time-consuming and difficult to interpret. As described herein, an integrated approach to measurement and analysis according to aspects of the present disclosure increases measurement speed by more than an order of magnitude (compared to known techniques) while maintaining high resolution. Shorter experiment duration enables new modes of investigation that produce comprehensive maps of electrochemical activity, rather than isolated fragments of information.

A measurement instrument 106 as described herein may refer to any type of circuit or machine capable of determining time-domain and/or frequency-domain information associated with an energy-conversion device 103. In some implementations, a measurement instrument may be configured to perform electrochemical impedance spectroscopy (EIS). EIS involves applying a voltage to the energy-conversion device 103 and measuring the resulting current. The response of the energy-conversion device 103 to this excitation may be recorded by the computing system 109 and used to determine metrics associated with the energy-conversion device 103 as described below.

EIS is ubiquitously applied to identify the physicochemical processes that govern the performance of energy-conversion devices. However, observed impedance phenomena are often difficult to disentangle and interpret meaningfully. Increasing measurement throughput can aid deconvolution, but this strategy is limited by the speed of EIS and a dearth of scalable analysis methods. The systems and methods described herein provide an approach to quickly collect and coherently analyze large volumes of electrochemical data.

The disclosed systems and methods accelerate impedance characterization by combining rapid measurements in the time and frequency domains, which are accurately and interpretably transformed using a DRT-DOP model. Such systems and methods provide excellent agreement with EIS across a broad range of timescales while decreasing measurement time by more than an order of magnitude.

Systems and methods described herein harness large hybrid time/frequency-domain datasets and synthesize information from hundreds of spectra with algorithms, thereby constructing detailed electrochemical maps. Such maps are complemented by rapid time-resolved measurements to further elucidate underlying physical mechanisms.

The mapping approaches described herein richly characterize physicochemical relationships that are difficult or impossible to decipher with conventional measurement and analysis methods. Mapping as described herein generally refers to the aggregation of many (e.g., hundreds to thousands) measurements to construct multi-dimensional datasets which may be analyzed with specialized algorithms.

Electrochemical energy conversion devices have intricate architectures comprising different materials, interfaces, microstructures, and length scales. To determine design principles that will drive improvements, designers must first understand how these components, and the physical processes occurring within them, govern device performance. EIS provides a non-destructive, in-situ means to resolve different physicochemical processes by their characteristic relaxation frequencies, making it a ubiquitous technique for the analysis of electrochemical systems. However, the impedance spectra of energy conversion devices reflect their structural complexity: not only do a large number of processes contribute to the observed impedance, but such processes often overlap in the frequency domain and are strongly influenced by measurement conditions like temperature, local chemistry, operating history, and electrical bias. This limits the interpretability of any individual EIS measurement: because a single spectrum represents a single system state, various models may explain the data equally well. To overcome this ambiguity, numerous measurements under different conditions are required to arrive at a meaningful understanding of the system, which explains the slow, time consuming nature of known processes for in-situ electrochemical characterization of electrochemical energy conversion devices.

Best practice dictates collecting spectra under varied conditions to clarify the underlying processes; however, EIS relies on time-consuming frequency-domain measurements, placing practical limits on data volume. It is often impractical or impossible to collect sufficient data within the allowable time frame or the stable lifetime of the sample. Accelerated electrochemical measurements are also of great interest for combinatorial and high-throughput materials studies and online diagnostics. Such applications have prompted an investigation of rapid time-domain measurements as an alternative to EIS; however, these efforts have been hindered by instrument sampling rate limitations and high-frequency artifacts, low signal-to-noise ratio and resolution, inconsistency with EIS results, and difficulties in model selection for data analysis. Some efforts have been made to join time- and frequency-domain measurements, which allows access to higher frequencies than time-series data alone. However, this approach faces the same issues that are intrinsic to time-domain measurements with the added challenge of merging heterogeneous data from the two domains. Thus, although the concept of acceleration via the time domain has been demonstrated, time-domain and hybrid time/frequency-domain measurements have yet to match the quality or interpretability of EIS in practice.

The advent of faster measurement techniques will also require methods for meaningful interpretation of large electrochemical datasets, which may contain hundreds or thousands of spectra. Most EIS analyses are fundamentally one-dimensional: each spectrum is processed in isolation, although results may be aggregated for review. In contrast, multi-dimensional data processing routines—which consider multiple spectra representing different system states—address the inherent uncertainty of impedance deconvolution.

Although some approaches to combine information from a limited number of spectra have been proposed, the lack of scalable, generalizable multi-dimensional methods presents another barrier to the study of complex electrochemical devices.

The systems and methods described herein provide techniques for rapid, precise electrochemical measurement and large-scale multi-dimensional analysis. The systems and methods described herein may be performed by a computing system 109 as illustrated in FIG. 2.

FIG. 2 is a block diagram of a computing system 109 capable of using one or more measurement instruments 106 to collect data associated with an energy-conversion device 103. The one or more measurement instruments 106 may be comprised by the computing system 109 or in communication with the computing system 109 via a communication interface 209. The computing system 109 may be configured to perform as a controller as described herein. The computing system 109 may be implemented in the environment of FIG. 1. The computing system 109 may be a personal computing device, a laptop device, a mobile computing device, a server blade, an Internet appliance, a virtual computing device, a distributed computing device, a cloud-based computing device, or any appropriate processor-driven device.

The computing system 109 may comprise one or more processors 203 connected to a bus. The computing system 109 may comprise a storage device 206, memory 212 storing one or more applications and an operating system, and one or more input/output ports such as a user interface 215 and a communication interface 209.

Examples of the processor as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

The systems and methods described herein provide a versatile, hybrid time/frequency-domain approach that precisely matches EIS while accelerating measurement by a factor of 20 to 50. The techniques described herein are enabled by a DRT-DOP model, which enable robust transformation between domains and physical interpretation of the data. The DRT-DOP representation described herein is broadly applicable because it treats both resistive-capacitive relaxations and constant-phase behavior without an apriori model.

The hybrid technique described herein provides several important capabilities, including mitigation of time-domain perturbations, measurements under DC bias, and time-resolved characterization of evolving systems.

Systems and methods described herein provide a framework for the assimilation of numerous spectra in a multi-dimensional state variable space, implementing scalable algorithms to identify and characterize individual electrochemical processes. This enables a new paradigm of analysis in which high-throughput measurements are harnessed to construct detailed maps of electrochemical activity and reveal trends that cannot be resolved with conventional approaches.

Development of the DOP is motivated by limitations of the DRT. The DRT is a function of log-timescale, denoted γ(ln τ), that describes the magnitude of RC relaxation processes occurring in an electrochemical system. The relationship between the impedance, Z(ω), and the DRT is given by Equation 1:

$${Z}_{γ} ( ω ) = {\int }_{- ∞}^{∞} \frac{γ ( ln τ )}{1 + j ω τ} d ln τ ,$$

where
Z=the impedance,
γ(ln τ)=the voltage response of a distribution of relaxation times,
τ=the time constant,
ω=the angular measurement frequency, and
j=the imaginary number.

As suggested by the RC impedance expression (1+jωτ)−1 that appears inside the integral, the DRT represents an infinite series of RC elements spanning all timescales. Using Equation 1, the distribution γ(ln τ) may be estimated from impedance data. Although DRT estimation from impedance data is an ill-posed inversion problem, an extensive body of work has established efficient numerical methods that encode the principle of parsimony to determine the solution that most credibly explains the data. As described herein, a self-tuning hierarchical Bayesian approach may be used to solve the inversion problem. This approach has demonstrated, reliable accuracy and suppresses false peaks as described below.

The interpretation of the DRT can be understood through its relation to equivalent circuits: the ZARC (Cole-Cole) element corresponds to a single peak in the DRT at τ=τ0, where τ0 is the characteristic time constant. As the degree of dispersion of the ZARC element increases, the peak width increases while the peak height decreases; the total area under the peak is equal to the ZARC resistance. In general, each peak in the DRT represents an individual electrochemical process. Thus, the DRT can be used to identify and separate distinct contributions to the impedance, which is particularly useful when a pre-existing, well-defined model is not available.

However, the DRT is poorly suited to describe behavior that diverges from RC relaxation. For this reason, ideal circuit elements are commonly incorporated into the DRT model to describe inductance, ohmic resistance, and/or capacitance. In other cases, a constant phase element (CPE) may be incorporated to capture phenomena such as diffusion. The CPE impedance is given by Equation 2:

$${Z}_{CPE} = \frac{1}{{{Q}_{0} ( j ω )}^{n}} ,$$

where ZCPE=the CPE impedance,
Q=the electrical charge
ω=the angular measurement frequency, and
j=the imaginary number, and
n=the phase exponent,
   where 0≤n≤1 describes the phase angle, with n=0 describing an ideal resistor, n=1 indicating an ideal capacitor, and intervening values representing fractional-order behavior typical of transport processes. However, this requires case-by-case analysis and model adjustment. In addition, optimizing the CPE exponent n introduces undesirable non-linearity into the DRT estimation procedure. For these reasons, CPEs are most often omitted from DRT analysis; instead, any fractional-order behavior is treated approximately with the DRT. Unfortunately, this has detrimental impacts on subsequent analyses because the equivalent DRT for CPE or near-CPE impedance is an infinite series of peaks that grow without bound in the limit τ→0. Not only is it impossible to construct the infinite peak series with DRT estimation algorithms, but these peaks may interact with and obscure DRT peaks corresponding to other electrochemical processes. This limits the applicability and interpretability of the DRT for systems that exhibit fractional-order behavior.

To overcome this limitation, we adopt a phasance concept which generalizes the treatment of resistance, inductance, capacitance, and CPEs. A phasance is a fractional-order circuit element with impedance given by Equation 3:

$${Z}_{p} ( ω ) = {P ( j ω )}^{v}$$

where P=the phasance magnitude,
ω=the angular measurement frequency,
j=the imaginary number,
ν=phasance order, and
   where −1≤ν≤1=the fractional order of the phasance magnitude. The integer values ν=−1, ν =0, and ν=1 correspond to ideal capacitance, resistance, and inductance, respectively. When −1<ν<0, the phasance produces a pseudo-capacitive response with constant phase θ=νπ/2<0 (analogous to the CPE) that grows without bound as frequency decreases. The positive range 0<ν<1 corresponds to a pseudo-inductive response with constant phase θ=νπ/2>0 that grows without bound as frequency increases.

Because the number of phasance elements and their ν values are not known a priori, the DOP, denoted ρ(ν), may be introduced which represents an infinite series of phasances spanning all ν values from −1 to 1. The DOP draws inspiration from the DRT, representing a set of discrete processes with a distribution to enable flexible analysis and advantages in numerical optimization.

Analogous to the DRT, the impedance of the DOP is given by integrating the product of the distribution magnitude and the phasance impedance over ν as illustrated by Equation 4:

$${Z}_{ρ} ( ω ) = {\int }_{- 1}^{1} ρ ( v ) {( j ω )}^{v} dv ,$$

where
Zρ=the phasance impedance,
ρ(ν)=the DOP,
ω=the angular measurement frequency, and
j=the imaginary number, and
ν=the phasance order.

For intuitive visualization, the ν axis may be inverted such that pseudo-inductive peaks that are relevant at high frequencies (ν>0) appear on the left, while pseudo-capacitive peaks that affect low-frequency impedance (ν<0) appear on the right. This aligns the DOP with Nyquist plots and the DRT, placing short-timescale processes on the left and long-timescale processes on the right. Because the magnitude of the DOP impedance is exponentially frequency dependent and the units of phasance are Ω·s^{ν}, the normalized DOP may be defined by Equation 5:

$$\tilde{ρ} ( v ) = \{ \begin{matrix}ρ ( v ) \cdot {τ}_{-}^{- v} & for & v \leq 0 \\ ρ ( v ) \cdot {τ}_{+}^{- v} & for & v > 0 ,\end{matrix}$$

where ρ(ν)=the DOP, and where τ− and τ+ are characteristic time constants that may be selected based on the timescales of interest for the pseudo-capacitive and pseudo-inductive regions of the DOP, respectively. The normalized distribution has units Ω, which can be interpreted to represent the magnitude of the DOP impedance at the selected timescales (τ− and τ+). DOP results are presented in terms of ^{˜}ρ to clarify visualization and interpretation.

Combining the DRT and DOP in series, the impedance of nearly any linear time-invariant (LTI) system can be represented by Equation 6:

$$Z ( ω ) = Z γ ( ω ) + Z ρ ( ω ) ,$$

where Z(ω) is the overall impedance, Zγ(ω) is the impedance contribution from the DRT, and Zρ(ω) is the impedance contribution from the DOP.

The DOP captures capacitive, resistive, inductive, and CPE behavior, removing the need to incorporate additional circuit elements into DRT analysis or preprocess the data to remove such effects. The series DRT-DOP model separates impedance responses with different frequency dependencies, treating RC behavior with the DRT and constant-phase behavior with the DOP to simplify interpretation. In addition, the DRT-DOP model can be optimized via efficient convex optimization algorithms to simultaneously estimate both the DRT and the DOP with comparable computational cost to conventional DRT estimation as described below.

### Validation of DRT-DOP Analysis

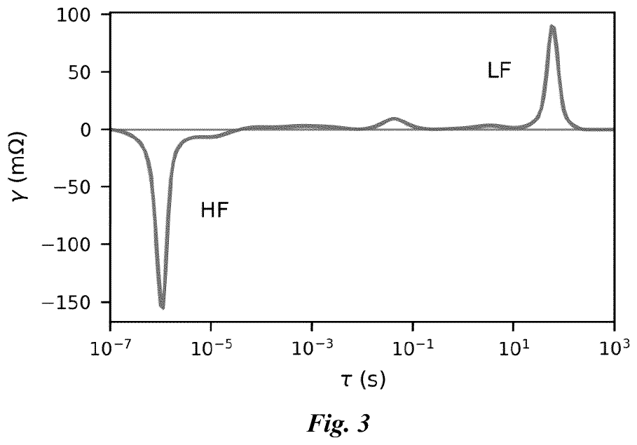

To illustrate how the DOP enhances DRT analysis, consider the impedance of a commercial Li-ion battery (LIB) with a LiNiₓMn_{y}Co_{1-x-y}O₂ (NMC) cathode (Molicel INR-18650-M35A) and nominal capacity of 3400 mAh. EIS was performed at 100% state-of-charge (SOC) from 100 kHz to 10 mHz with 10 points per decade (ppd), using a galvanostatic root-mean-square (RMS) excitation amplitude of 120 mA that results in a maximum current of 170 mA (0.05 C). The spectrum displays diverging impedance at both high and low frequencies. These unbounded impedance responses are often observed in LIBs: the high-frequency response, denoted HF, may represent a skin effect in the active material, while the low-frequency response, denoted LF, indicates transport processes. First, a conventional DRT inversion may be applied to the spectrum, producing a distribution as illustrated in FIG. 3. The DRT is dominated by a series of diverging negative and positive peaks at the short- and long-timescale boundaries, corresponding to the HF and LF impedance, respectively. The intermediate-timescale region of the DRT (10⁻⁶ s≤τ≤1 s) is hard to discern, in part because the HF and LF peaks are so dominant and in part because the HF and LF peaks interact and interfere with the intermediate-timescale peaks.

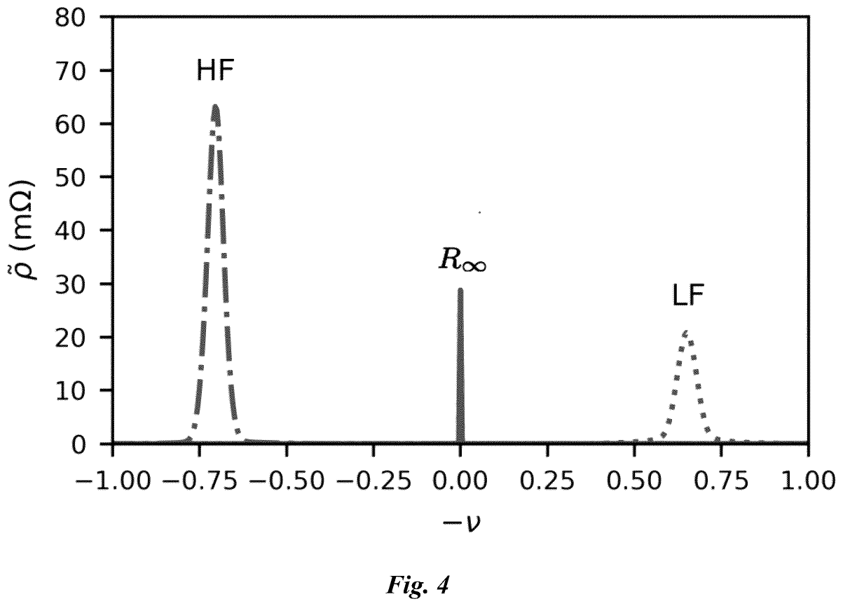

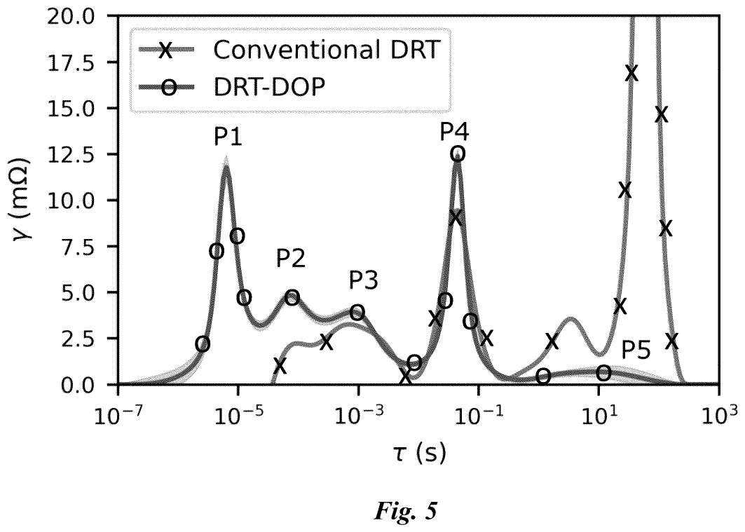

Next, the DRT-DOP model may be applied to estimate the DOP and the DRT without interference from constant-phase impedance as illustrated in FIG. 4. In this example, the DOP contains three peaks: a large peak at −ν ≈−0.7 representing the skin effect (HF), a peak at ν=0 representing ohmic resistance, and a peak at −ν ≈0.65 representing transport (LF). The DRT component of the DRT-DOP model is then unperturbed by the HF and LF impedances, which are treated directly by the DOP, and instead captures the RC relaxations at intermediate frequencies. Each of these contributions can be separated and visualized in a Nyquist plot as shown in FIG. 5. This deconvolution allows the DRT portion of the DRT-DOP model to clearly resolve four peaks in the range 10⁻⁶ s≤τ≤10⁰ s, labeled P1-P4. In the conventional DRT, P2 and P3 are less clearly identified, while P1 is completely obscured by the onset of the negative HF peaks. The DRT-DOP model also suggests a shallow peak at τ≈10¹ s (P5), but this may represent a slight interaction between the DRT and the DOP in the long-timescale region (as indicated by the wider credible interval of the DRT in this region) and may thus be associated with the LF DOP peak.

Whereas the conventional DRT result provides a nebulous explanation of the LIB impedance, the DRT-DOP model produces a straightforward interpretation. The HF DOP peak may be assigned to the skin effect, the central DOP peak to ohmic resistance, and the LF DOP peak to transport. The four main DRT peaks (P1-P4) then represent RC relaxations that can be studied separately from the constant-phase responses, as explored below.

It may also be noted that the LIB impedance is asymptotically inconsistent with the conventional DRT: as τ→0 or τΘ∞, γ does not decay to zero. The DRT-DOP model resolves this by capturing these non-asymptotic effects in the DOP. The conventional DRT and DRT-DOP models both fit the data well, as evidenced by randomly distributed impedance residuals and small chi-square goodness of fit values (χ²=3.0×10⁻⁴ and 2.8×10⁻⁴ for the DRT and DRT-DOP models, respectively, using modulus weighting). This indicates that the DRT-DOP model appropriately captures the measured impedance while simplifying its interpretation relative to the conventional DRT result.

### Accelerated Measurement Via Hybrid Time/Frequency Analysis

Conventional time-domain measurement for accelerated impedance characterization is limited in practice as the highest accessible frequency is limited by the signal rise time and sampling rate allowed by hardware and software capabilities. Conventional hybrid measurements that use EIS to probe high frequencies and time-domain data to capture low frequencies fail to provide utility comparable to conventional EIS measurement. One limiting factor is the intrinsic resolution of time-domain data: relaxations at different timescales overlap more strongly in the time domain than in the frequency domain, which hinders separation and analysis of individual processes. Another key challenge is the method for integrating data from the two domains. The vast majority of efforts have used the fast Fourier Transform (FFT) to transform time-domain current-voltage data to frequency-domain impedance, but the transform is sensitive to noise and windowing effects, limiting the accuracy and usable frequency range of the transformed data. Alternatively, equivalent circuit models have been applied, but these require costly fitting procedures and a priori selection of an appropriate model. Conventional methods of calculating the DRT directly from time-domain data or from combined time- and frequency-domain data have significant limitations that deter the practical use of hybrid measurements. The time-domain component has been used to inform only relatively long timescales (τ≳ 10-1 305 s), precluding the acceleration of measurement at shorter timescales. Furthermore, previous studies focus on LIBs, examine only open-circuit conditions, and use large excitation amplitudes in the time domain that almost certainly violate assumptions of linearity and may cause sample degradation. Most importantly, these methods have undergone insufficient validation and have shown only poor to moderate agreement with conventional EIS, which suggests that the accuracy of time-domain results is limited.

The systems and methods described herein provide an approach to analysis that addresses these issues, demonstrates precise agreement with conventional EIS results, and requires no specialized equipment. As described herein, a DRT-DOP model is used to seamlessly combine time- and frequency-domain data. Rather than treating each data type separately, the model simultaneously fits both datasets over the full frequency/timescale range of interest, thereby avoiding artifacts at the timescale boundary between measurements. In order to fit the model to time-domain data, the voltage signals of the DRT and DOP in response to a series of applied current steps are derived as follows in Equation 7:

$${υ}_{γ} ( t ) = {\sum }_{k = 1}^{K} Δ {i}_{k} \cdot u ( t - {t}_{k} ) {\int }_{- ∞}^{∞} γ ( ln τ ) ( 1 - {e}^{- ( t - {t}_{k} ) / τ} ) d ln τ ,$$

### and Equation 8:

$${υ}_{ρ} ( t ) = {\sum }_{k = 1}^{K} Δ {i}_{k} \cdot u ( t - {t}_{k} ) {\int }_{- 1}^{1} ρ ( v ) \frac{{( t - {t}_{k} )}^{- v}}{Γ ( 1 - v )} dv ,$$

where
v_{γ}(t)=the voltage response of the DRT,
v_{ρ}(t)=the voltage response of the DOP,
Δiₖ=the size of the kth current step,
tₖ=the time at which the kth step is applied,
u(t−tₖ)=a Heaviside step function at t=tₖ,
γ(ln τ)=the DRT,
ρ(ν)=the DOP, and
Γ is the gamma function. The time-domain voltage of the full DRT-DOP model is then given by Equation 9:

$$v ( t ) = {v}_{0} ( t ) + {v}_{γ} ( t ) + {v}_{ρ} ( t ) ,$$

where v₀(t) is the initial voltage function, which depends on the initial state and history of the sample, but in many cases can be treated as a constant, v_{γ}(t) is the voltage response of the DRT, and v_{ρ}(t) is the voltage response of the DOP. Combining the time-domain model with the frequency-domain model enables the estimation of the DRT and DOP from hybrid data using the same hierarchical Bayesian algorithm described herein. The voltage model may also be applied to estimate the DRT and DOP from time-domain data only. This is particularly useful in scenarios in which no frequency response analyzer is available and/or rapid measurements are necessary to capture the evolution of a system over time, as demonstrated below.

As for EIS, the amplitude of the time-domain current signal must be small enough to ensure a pseudo-linear response. Although the exact requirements for linearity depend on the system, EIS measurements are often configured for a 10 mV RMS excitation, corresponding to a maximum voltage perturbation of 14 mV. This may also serve as a reasonable heuristic for selecting the time-domain current step amplitude, since constraining the voltage amplitude ensures that the current amplitude is adjusted to the impedance of the sample. Because the voltage perturbation serves as an indicator of how much the samples state changes in response to the applied current, this may also provide for a linear response, whether the measurement is performed at open circuit or under DC load. The frequency- and time-domain components of the hybrid measurement should use the same DC offset and AC excitation amplitude to ensure concordance.

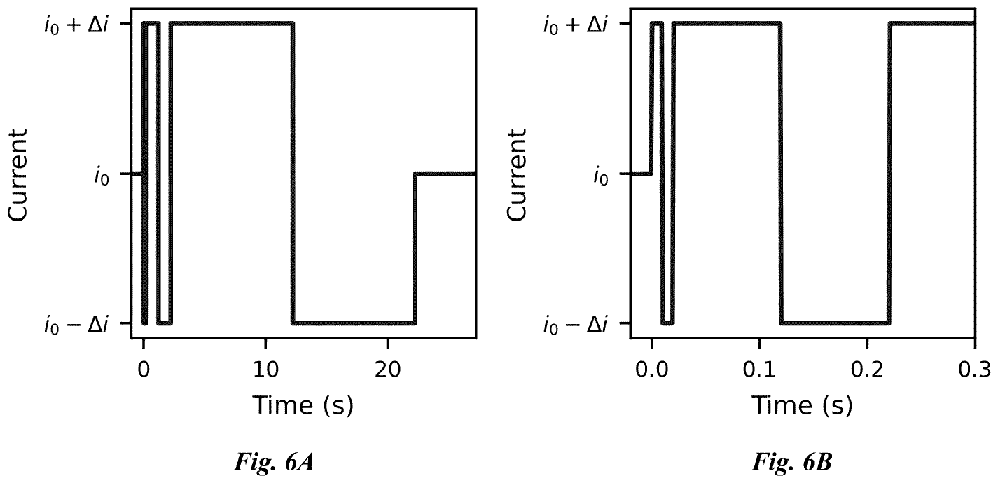

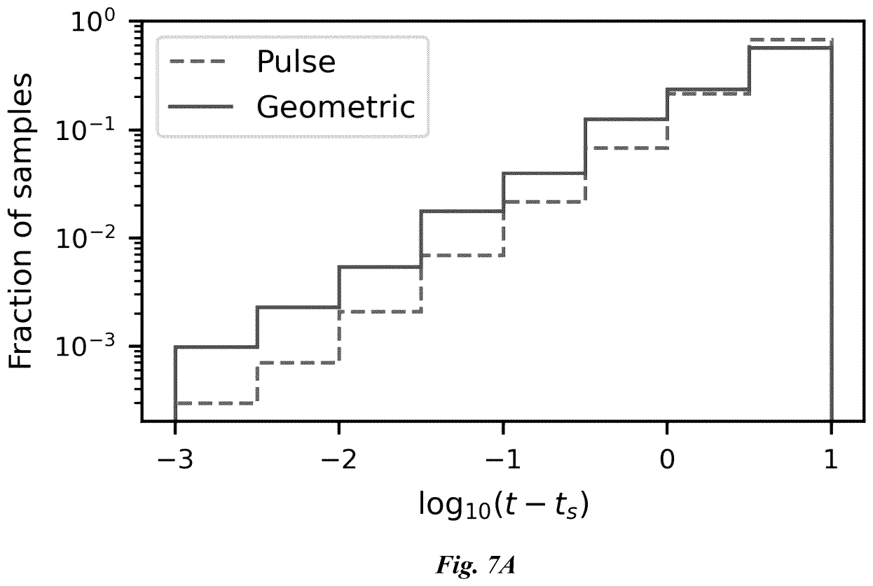

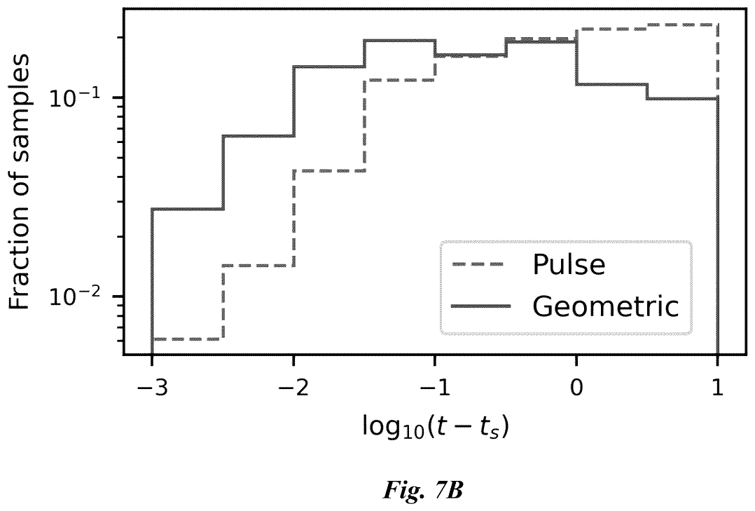

In some implementations, a sequence of current steps may be used in the time-domain measurement. Employing a simple current pulse may show some disadvantages in some scenarios. First, because the time-domain sample period is constant, the pulse produces far more data at long timescales than at short timescales. In addition, the response to any individual current step may be perturbed by noise that is difficult to distinguish from the true relaxation. Therefore, a well-designed time-domain experiment may include multiple current steps in sequence such that the sample response is observed multiple times. This has the dual benefit of increasing the number of data points at short timescales and increasing confidence in the true signal. For this reason, a current signal may be implemented that improves data uniformity while minimizing measurement duration. The signal may be a series of current steps at geometrically spaced time intervals spanning the timescale decades of interest. This signal may be referred to as a geometric step pattern. For example, to characterize the timescale range 10⁻³ s<τ<10¹ s with a sample period of 1 ms, step intervals may range from 10 ms to 10 s, as shown in FIGS. 6A and 6B. FIG. 6A illustrates the geometric step pattern, assuming a 1 ms sample period and 10 s maximum step duration. FIG. 6B illustrates a magnified view of the shortest step intervals for the geometric signal in FIG. 6A. This enhances information density at short timescales that approach the sample period, as shown in FIGS. 7A and 7B, without substantially increasing duration. To further improve data uniformity, reduce data storage requirements, and reduce computational load, the time-domain data may in some implementations be down-sampled with an antialiasing filter.

The hybrid approach described herein involves a much larger number of data points (typically >1,000) than EIS analysis, which tends to increase computational cost. For example, the numerical evaluation of the integrals in Equation 7 required to construct matrices for the DRT inversion can become computationally expensive. However, the evaluation may be dramatically accelerated by reducing the operation to an interpolation. In addition, the linearity of the DRT-DOP model enables efficient convex optimization of parameters. As a result, the hybrid inversion algorithm described herein converges quickly (<2 s in most cases).

### Li-Ion Battery

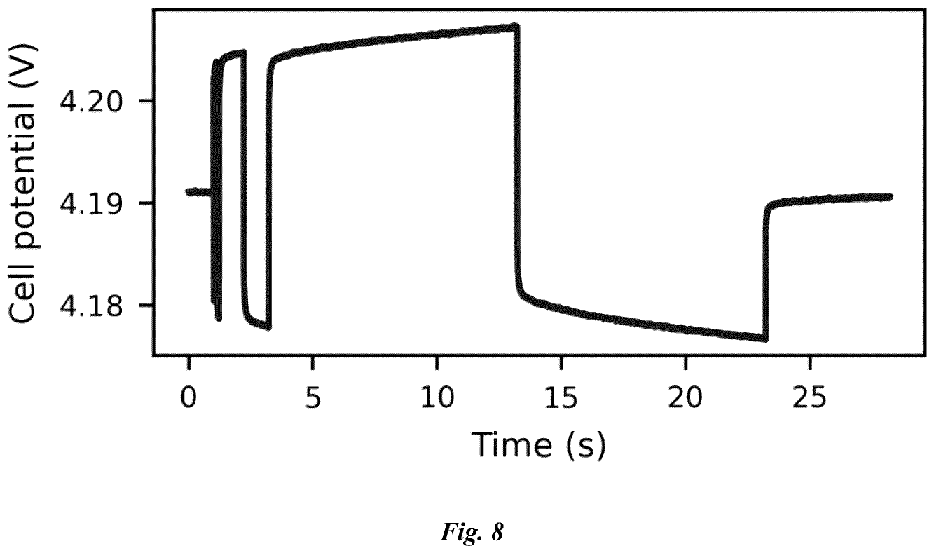

To illustrate the hybrid methodology described herein, consider the LIB discussed above at 100% SOC. A high-frequency EIS measurement may be performed, for example, from 100 kHz to 100 Hz at 10 ppd with a galvanostatic RMS excitation amplitude of 120 mA. The cell may then be allowed to rest for 2 s, after which a geometric step signal centered at open circuit may be applied with amplitude matched to the EIS excitation signal as illustrated in FIG. 8. The time-domain measurement may be performed with a sample period of 1 ms, providing information for τ≳10⁻³ s, while the EIS portion provides information for τ≲10⁻³ s. While conventional EIS would require 27 minutes, the entire measurement using the systems and methods of the present disclosure lasted only 40 s—9.4 s for the EIS component and 28.2 s for the time-domain component (plus 2 s rest time)—a 40-fold decrease in measurement duration. A DRT-DOP model may next be fitted to the hybrid time/frequency data. The DRT-DOP model also provides a means to recover the sample impedance from hybrid time/frequency data by evaluating Equations 1 and 4 described above.

The hybrid technique of the methods and systems of the present disclosure effectively replicates the results of conventional EIS in a fraction of the time. While EIS measurements may be executed more quickly by collecting fewer points per decade, particularly in the low-frequency region, this comes with a substantial loss of resolution. In general, reducing the density of EIS data collection will reduce distinction between overlapping processes, such as P2 and P3 of the LIB DRT. In the case of the LIB, the 5 ppd measurement requires 14 minutes—20 times longer than the measurement using the systems and methods of the present disclosure—and still provides a less informative result.

In some implementations, such as in practical systems without a frequency response analyzer, batteries may be evaluated with purely time-domain techniques to monitor battery health and/or SOC. The DRT-DOP inversion provides an accurate impedance estimate from time-domain voltage data alone. Although the maximum sampling rate of the instrument limits the highest accessible frequency, time-series data can characterize the moderate to long timescales that describe charge transfer and transport. Thus, useful information can be obtained for state-of-health and SOC estimates even without frequency-domain measurements.

The DRT and DRT-DOP models described herein also provide utility for predicting the LIB response in the time domain. As an example, a 400 s charge-discharge experiment was conducted: first, a 170 mA discharge current was applied for 200 s, and then a 170 mA charging current was applied for 200 s. The voltage response of the LIB was predicted with three models: a conventional DRT trained with EIS data, a DRT-DOP model trained with EIS data, and a DRT-DOP model trained with hybrid data. In all cases, the training data effectively extended to a minimum frequency of ˜10 mHz or maximum equivalent timescale of ˜16 s. Whereas the conventional DRT prediction quickly plateaus and diverges from the measured voltage, both DRT-DOP models of the present disclosure track closely with the measured response over the entire duration. The improved extrapolation may be attributed to the LF DOP peak that describes the diffusion process, further highlighting the utility of the DOP for establishing predictive, interpretable battery models. The effect of the DOP can also be visualized in terms of impedance, which contrasts the RC-type relaxation of the DRT model at low frequencies with the constant-phase DRT-DOP response. In addition, the close agreement of the predictions from the EIS and hybrid DRT-DOP models reinforces the consistency and accuracy of the hybrid methodology.

### Proton-Conducting Ceramic Electrochemical Cell

As an illustration of the versatility of the hybrid technique of the present disclosure, consider a reversible protonic ceramic electrochemical cell (PCEC) comprising a BaCe_{0.4}Zr_{0.4}Y_{0.1}Yb_{0.1}O_{3-δ} (BCZYYb4411) electrolyte, Ni-BCZYYb4411 fuel electrode (negatrode), and BaCo_{0.4}Fe_{0.4}Zr_{0.1}Y_{0.1}O_{3-δ} (BCFZY4411) air/steam electrode (positrode) with an active area of 0.32 cm². The supporting negatrode layer is around 0.8 mm thick, while the electrolyte and positrode layers are each around 10 μm thick. For the characterization, the cell was operated at 550° C. with dry hydrogen and humidified 21% O₂/79% Ar fed to the fuel and air/steam electrodes, respectively. A conventional EIS measurement was performed from 1 MHz to 100 mHz at 10 ppd with a 10 mV RMS potentiostatic excitation amplitude. The corresponding DRT consists of a high-frequency peak at τ≈10-7 s followed by several broad peaks at longer timescales. At least four peaks are visible, but the strong dispersion and overlap make it difficult to determine whether additional peaks might be present. The DOP consists of a pseudo-inductive peak at −ν≈−0.9, which describes resistive-inductive behavior at high frequencies approaching ideal inductance, and an ohmic peak at ν=0. No pseudo-capacitive peaks (−ν>0) are observed, consistent with the relaxation of the imaginary impedance to zero at low frequencies.

In contrast to the commercial LIB described above, which exhibits very stable voltage and high signal-to-noise ratio, the laboratory-scale PCEC presents a substantially higher noise level, which may be due to fluctuations in temperature and gas flow in the test fixture. The noise manifests both as scatter in the frequency-domain impedance, especially at low frequencies, and as fluctuations in the time-domain voltage. To examine the effect of these systematic perturbations, three hybrid measurements of the cell were performed under the same conditions. Hybrid measurements may be performed by first collecting impedance from 1 MHz to 1 kHz at 10 ppd and then applying a geometric current signal as described above with a maximum step length of 1.0-1.5 s. The current steps were configured to produce a voltage response of the same magnitude as the EIS excitation. A sample period of 100 μs was used for the time-domain measurement to inform timescales as short as τ≈10-4 s, while the high-frequency EIS data informs timescales shorter than τ≈10-4 s. The DRTs from repeated measurements exhibit substantial variation for τ≳10-2 s, indicating voltage perturbations at this timescale. Unlike EIS, which probes a single frequency, the time-domain measurement simultaneously examines a broad range of frequencies and makes the removal of background noise signals difficult.

To mitigate the effect of these perturbations, a model for time-domain background correction may be implemented based on the principle that the true sample response is linear time-invariant, whereas the superimposed background signal is uncorrelated with the current excitation signal. The model is implemented by incorporating a modified Gaussian Process that acts as a filter for time-domain perturbations into the DRT-DOP model.

In contrast to existing hybrid approaches, the systems and methods described herein show potential to directly replace conventional EIS across a broad range of frequencies and electrochemical systems. This is enabled by several key developments. For example: time- and frequency-domain signals are aligned to ensure consistency and linearity; a new signal design extends the utility of time-domain data to shorter timescales; rigorous validation shows strong qualitative and quantitative agreement with conventional EIS; and time-domain background estimation enables application of the hybrid technique to noisy systems with reproducible, accurate results. As described below, the hybrid technique can characterize devices under DC load, further expanding its applicability.

Electrochemical Mapping with Rapid Measurements

The hybrid technique detailed herein enables the collection of large amounts of electrochemical data. This increase in measurement throughput may provide deeper insight into the behavior of electrochemical devices. Changes in the impedance may be analyzed as a single state variable of interest, such as temperature or partial pressure, is varied. This represents two-dimensional (2D) analysis: impedance is evaluated as a function of frequency and the state variable to investigate the influence of the state variable on different processes. However, there are often multiple state variables of interest, motivating the development of generalized methods for higher-dimensional analysis. In addition, conventional EIS analyses rely on independent regressions of individual spectra. Given the inherent ambiguity of impedance spectra, the ability to aggregate information from multiple spectra is crucial to robust interpretation.

Multi-spectrum regression with physics-based or equivalent circuit models has been demonstrated, most often using several spectra to improve confidence in shared parameters and/or identify trends such as temperature activation. However, generalization of this technique is limited by the requirement for a well-defined parameterized model and its scalability to larger numbers of spectra and/or additional dimensions. Multi-dimensional DRT inversion has also been proposed to reduce the influence of measurement noise and clarify peaks and trends in the DRT relative to one-dimensional (1D) inversion. A deep neural network approach was applied to simultaneously determine the DRTs of 25 solid-oxide fuel cell (SOFC) spectra as a function of pO2 and temperature. The variation of state variables represents three-dimensional (3D) analysis, a step towards self-consistent analysis of multi-dimensional EIS data. However, the DRT is only a starting point for analysis; physical interpretation may require the identification and quantification of discrete processes. In addition, the scalability of such conventional approaches to much larger datasets—containing hundreds to thousands of spectra, potentially including hybrid measurements with many more points per spectrum—has yet to be established.

The systems and methods described herein provide a framework for coherent analysis of large, multi-dimensional electrochemical datasets containing frequency- and/or time-domain measurements. Based on the hybrid DRT-DOP inversion method introduced above, practical algorithms for multi-dimensional regression, model identification, and deconvolution of overlapping processes may be developed. This technique may be referred to as electrochemical mapping because it reveals and describes physical processes throughout a state variable space of interest.

### Li-Ion Battery

The behavior of batteries under load, while charging or discharging, is highly relevant to real-world performance. While the changing SOC induced by a DC current is problematic for conventional EIS characterization, hybrid measurements are fast enough to capture a pseudo-stable snapshot of the cell. For example, consider a measurement performed at a DC current of 1.0 C: over the course of a 30-minute EIS measurement, the battery experiences a 50% change in SOC, in contrast to just a 1% change in SOC during a 40-second hybrid measurement. This capability may be exploited to characterize the Molicel LIB as a function of SOC during discharge cycles at different C rates.

SOC may be defined by Equation 10:

$$SOC = 100 \cdot ( 1 - \frac{{Q}_{discharged}}{{Q}_{nominal}} ) ,$$

where Q_{discharged} and Qₙₒₘᵢₙₐₗ are the discharged and nominal capacity of the battery, respectively. In each discharge cycle, the DC discharge current was applied while hybrid measurements centered at the DC current were performed continuously until the cell reached 50% SOC, thereby capturing hybrid data as a function of SOC without interrupting the discharge cycle. C rates ranging from 0.1 C to 1.0 C in 0.1 C increments were tested. The order of experiments was randomized and measurements were repeated for several C rates to decouple aging effects from C-rate effects.

Discharge curves may be extracted using the hybrid measurements. The voltage curves exhibit plateaus near 90% and 65% SOC, with a local maximum in slope in the intervening region at 75% SOC, as indicated more clearly by differential discharge curves. The plateaus at 90% and 65% SOC may be attributed to phase equilibria in the graphite anode, whereas the peak in slope at 75% SOC represents a first-order phase transition of the anode.

The DC discharge current results in a steadily decreasing baseline voltage during each hybrid measurement. This baseline voltage originates from the history and initial state of the cell (i.e., v₀(t) in Equation 9), not from the current steps applied within the measurement. To account for this, the baseline voltage may be estimated from the discharge curve and then subtracted from the measured voltage to produce baseline-corrected data. This enables a valid fit of the corrected time-domain data via the regular hybrid inversion method. Fitting each individual measurement within a single discharge test produces a series of 1D DRTs and DOPs that vary with SOC.

Visualizing the data as a 2D surface in the ln τ-SOC space provides a more comprehensive view of trends in the DRT and DOP. Incorporating the C rate dimension, the DRT and DOP for the full set of discharge experiments defines a 3D hypersurface in the ln τ-SOC-C-rate space. The concept of structure in the full state variable space has important applications for analysis, as discussed below. The treatment of the DRT and DOP as multi-dimensional (hyper)surfaces provides a number of benefits. Whereas the 1D DRT represents a single state of the system in isolation, the DRT surface indicates how the distribution varies throughout the state variable space. This has applications for multi-spectrum DRT-DOP regression, which can be viewed as the estimation of the DRT and DOP surfaces. Physical intuition dictates that similar states should have similar DRTs and DOPs, implying that the surfaces should be smooth not only in the ln τ dimension (as in conventional 1D DRT inversion), but also in the additional state variable dimensions.

As described herein, a multi-spectrum DRT-DOP estimation algorithm uses a linear DRT-DOP model to compress raw data, enabling efficient convex optimization of the DRT and DOP surfaces, and thereby reducing the inversion ambiguity and clarifying trends in the distributions as compared to conventional methods of measurement. Because the correlation between 1D distributions declines with increasing distance in the state variable space, this optimization can be performed in relatively small batches of 5-15 spectra with negligible loss of information and low computational cost. The DRT and DOP surfaces can be further refined by applying filters to efficiently combine information from similar measurements and suppress erroneous features. An adaptive Gaussian filter that adjusts its length scale to the local curvature of the surface may be used to avoid smoothing out real features in the data.

The surface treatment also introduces the notion of multi-dimensional structure. Whereas electrochemical processes are represented by peaks in the 1D DRT, these processes manifest as ridges in the 2D DRT surface. Extending this concept to higher dimensions, 2D ridges become multi-dimensional sheets in three or more dimensions. Searching for sheets in the multi-dimensional space provides the opportunity to use far more data to identify and resolve discrete processes than is available in any single measurement or 1D distribution. In addition, by using trends in each process as a function of SOC and C rate, the most plausible time constant and magnitude for each process can be predicted even in regions in which they are not clearly resolved, as described below.

To identify sheets in the DRT surface, a semi-quantitative probability function may be developed that indicates the likelihood that a sheet exists at any point on the surface. This sheet probability function serves as a sensitive indicator of distinct processes by considering the topography of the DRT surface. The sheet probability function is a probabilistic tool that incorporates numerous spectra to highlight plausible, physical interpretations of the data. The sheet probability function for the 0.7 C test indicates five distinct processes, corresponding to P1-P5 identified in the above open-circuit analysis. P5 represents the transport process that is primarily captured by the LF DOP peak, as described above. Examining the sheet probability function across all discharge tests confirms that this sheet structure consistently appears across all C rates.

Although the sheet probability function allows for the identification of different processes that may be present in the DRT surface, quantitative analysis requires the positions (time constants) and magnitudes (resistances) of the sheets to be determined as a function of the state variables, SOC, and C rate. To approximately determine the time constant of each sheet throughout the state variable space, a sheet-tracing algorithm may be implemented in three dimensions. The algorithm constructs each sheet by first drawing a line through the 2D In τ-C-rate space, and then propagating the line through the SOC dimension, allowing the line to translate and/or twist at each step along the SOC axis. Each step maximizes the joint sheet probability through which the line passes while minimizing physically improbable artifacts like sudden, discontinuous translations or twists.

To quantitatively describe each identified process, a multi-dimensional model deconvolutes the DRT surface into distinct processes based on the principle that each process defines a characteristic distribution (DRT contribution) that varies with the state variables. Next, each process may be parameterized and how the parameters depend on the state variables may be determined. Because the LIB DRT exhibits symmetric peaks with varying degrees of dispersion, a ZARC element may be used to describe each individual process. It should be appreciated other basis elements could be applied depending on the nature of the system. The ZARC element is parameterized by a characteristic time constant τ₀, magnitude R, and dispersion parameter 3. Physical intuition suggests that each parameter should exhibit a characteristic relationship with the state variables, but the functional form of these relationships is generally not known a priori. Therefore, the variation of each ZARC parameter may be described with a latent Gaussian Process (GP), which encodes the expectation that parameter values for neighboring coordinates in the state variable space are correlated; that is, sudden changes in parameter values are relatively improbable. The latent GP allows for the identification of a deconvolution that not only matches the DRT surface, but also represents plausible physical relationships. Because the GP captures trends in different processes with state variables, it also provides a means to separate overlapping features in the 1D DRT using information from the multi-dimensional surface, enabling the empirical identification of physical dependencies of different processes from ambiguous data with minimal prior knowledge of the governing physics.

For the LIB data, the range τ≤10^{-0.5} may be considered, including only P1-P4 in the GP-ZARC deconvolution, as P5 is associated with the DOP LF peak. The state variable input space for the latent GP includes SOC, C rate, and cycle number to account for aging effects. Because the LIB DRT hypersurface is a transformed representation of the data, the GP-ZARC model optimization is an indirect regression of the raw measurements. In total, over 750 spectra may be considered in the GP-ZARC optimization. The optimization problem is large: given four processes, each with three ZARC parameters at 750+ distinct state variable coordinates, there may be over 9,000 parameters in the model. However, the results of the sheet-tracing algorithm provide a first approximation of process time constants and resistance values to initialize the model near a suitable optimum, allowing the latent GP to identify meaningful trends in each process. The model may be implemented with a software package and optimized, such as by using the efficient L-BFGS algorithm. The GP-ZARC model converges to a close fit of the estimated DRT hypersurface with r2=0.992. P5, the transport process which includes both the small DRT sheet at τ≈100 s and the LF DOP peak, is quantified by integrating the DRT surface for τ>10^{-0.5} s and adding the result to the integrated area of the LF DOP peak. This direct quantification is possible because the DOP provides clear separation of the transport process from P1-P4.

The latent GP enables analysis of individual processes via partial dependence plots, which provide intuitive visualization of state variable interactions extracted from the hundreds of LIB spectra. These plots estimate the interaction of C-rate and SOC effects over all test cycles, excluding the influence of aging. It may be noted that there is an inverse correlation between the resistance of P1 and the ohmic resistance. Since P1 appears near the high-frequency boundary of the measurement, this may indicate that P1 extends to higher frequencies than those captured in the measurement and suggests that P1 and the ohmic resistance cannot be reliably separated, especially given the strong pseudo-inductive HF tail. For this reason, the sum of R∞ and P1 may be considered in the partial dependence analysis.

Given the short timescale of R_{∞} and P1, these processes can likely be attributed to the combination of electrolyte ohmic resistance, particle-particle contact, and the interface between electrodes and current collector. Their combined resistance is nearly independent of SOC at low C rate but increases during discharge at higher C rates. The resistance of these processes at any given SOC also increases substantially with increasing C rate. These trends indicate that one or more of the processes contained in R_{∞}+P1 is detrimentally affected by exposure to higher C rates. This can be understood by considering the long-term effects of high C-rate cycles as described below.

P2 corresponds to the leftmost semicircle after the HF pseudo-inductive tail in the Nyquist plot of FIG. 5, which is commonly assigned to Li migration through the solid-electrolyte interphase (SEI). Similar to P1, P2 is nearly constant or decreasing with decreasing SOC at low C rates but increases during discharge at higher C rates. Again, this pattern is described in greater detail below.

P3 and P4 appear in the frequency range commonly assigned to electrode charge transfer. P3 has a strong dependence on both C rate and SOC: it decreases in resistance as C rate increases and as the cell is discharged. These trends are consistent with electrode charge transfer: the C rate trend indicates Butler-Volmer-like overpotential activation, while the SOC trend reflects an increase in exchange current density. Like P3, P4 decreases in resistance with increasing C rate and decreasing SOC. However, P4 drops precipitously during the initial discharge to ˜90% SOC. This suggests that P4 corresponds to charge transfer at the NMC cathode: the initial decrease in resistance during discharge may be attributed to the initial lithiation of NMC, which should sharply increase the exchange current density. Meanwhile, P3 is associated with anode charge transfer. The more gradual decrease in resistance is consistent with the oversized graphite anodes used in commercial cells that ensure the anode is not fully lithiated at 100% SOC.

The transport processes captured by P5 decrease with increasing C rate until ˜0.5 C, at which point P5 begins to rise slowly with further increases in C rate. Along the SOC dimension, P5 exhibits a notable correlation with the differential discharge curve. P5 reaches local minima at SOCs approximately corresponding to the minima in dV/dQ and appears to rise near the first-order graphite phase transition at 75% SOC. This suggests that anode transport processes contribute significantly to P5, and that these processes are hindered by the phase transition.

To further investigate the influence of C rate, the partial dependence of each process on cycle number may be considered. R_{∞}+P1 varies systematically, increasing both during and after high-C-rate tests. The apparent prolonged response to C rate may be explained by slow solid-state Li-ion diffusion within or between electrode particles, which can take hours or days to reach equilibrium. This explanation can be applied to the observed partial dependence on C rate: under a large discharge current, concentration gradients develop within electrode particles, resulting in increased resistance. P2 follows the same pattern, suggesting that the SEI layer is impacted by a similar effect, although the magnitude of the effect is likely mitigated by faster liquid-phase transport in the SEI. Meanwhile, P3-P5 show small monotonic shifts over the course of the discharge tests, with P3 and P4 increasing and P5 decreasing over time. These can likely be attributed to minor aging effects during cycling, though we note that the size of the effect size is within the margin of error of the partial dependence analysis.

The capacitance of P2-P4 provides additional information. The order of capacitance magnitudes mirrors that of time constants: P2 has the smallest capacitance, while P4 has the largest. The capacitance of P2 declines slightly during initial discharge, then remains steady. The time constant and capacitance of P3 change moderately during discharge, consistent with the relatively small change in Li concentration in the anode. In contrast, the time constant and capacitance of P4 both decrease by an order of magnitude during discharge. The decrease in capacitance may be explained by the reduction of transition metal cations in the NMC cathode during discharge.

Findings from the LIB mapping analysis may be summarized as follows:
R∞+P1: electrolyte ohmic resistance, active material, and electrode/current collector interface. Higher C rates have a lasting detrimental effect on resistance, likely through development of Li-ion concentration gradients in electrode particles.
P2: Li migration through SEI. Higher C rates have a lasting detrimental effect on resistance, likely through development of Li-ion concentration gradients in SEI.
P3: Graphite anode charge transfer. Resistance decreases with increasing C rate (Butler-Volmer) and decreases steadily during discharge to 50% SOC (increasing exchange current density).
P4: NMC cathode charge transfer. Resistance decreases with increasing C rate and decreases rapidly during initial discharge.
P5: Solid-state Li-ion diffusion. Resistance is correlated to graphite phase transition.

The LIB mapping study provided herein presents several advantages relative to conventional EIS investigation. The hybrid technique described herein enables valid measurements under a DC discharge current, which is not feasible with conventional EIS. Systems and methods described herein also allow for the simultaneous capturing of the discharge curve and characterization of frequency-resolved losses, thereby providing rich data with no increase in measurement duration relative to standard charge/discharge cycles. In some implementations, analysis may be performed with time-domain measurements alone, providing insight into longer-timescale processes without the need for a frequency response analyzer.

Meanwhile, the coherent analysis of all 750+ spectra allows for the separation of overlapping processes, while the latent GP enables partial dependence analysis that concisely summarizes key state variable influences. The GP-ZARC model can also be applied to predict the DRT-DOP or impedance of the battery at unmeasured conditions. Such predictions may be more reliable for interpolation than extrapolation, but the trends revealed by the model can inform the development of well-defined functional relationships between individual processes and state variables. Physics-based models developed in this way can then be applied to more precisely analyze mapping data, using the identified physical relationships to constrain the deconvolution. The technique is also easily adaptable: variations of this template could consider additional state variables, examine different chemistries, and/or investigate long-term cycling to explore aging effects.

The analysis process described herein is sequential by design, which allows each successive step to harness a larger amount of information from multiple measurements. Surface regression and filtering integrate local trends to improve the accuracy and consistency of DRT-DOP estimation. Sheet tracing connects 1D peaks at different state variable coordinates to create a multi-dimensional process structure. Finally, the GP-ZARC model uses the sheet structure and all measurement data to determine descriptive parameters for each process with physically plausible relationships to the state variables. The sequential procedure is also highly scalable. Initial DRT-DOP inversion requires only seconds per spectrum, surface regression requires seconds per batch, filtering and sheet tracing are nearly instantaneous, and the GP-ZARC optimization may be performed in less than five minutes.

### Transient States Complement Static Measurements

As demonstrated by the analysis of LIB discharge behavior described above, rapid hybrid measurements allow the characterization of time-evolving systems by capturing pseudo-static states. This principle may be applied to examine the relaxation of a cell in response to changes in atmosphere.

These results highlight several additional benefits of the rapid measurement techniques described herein. Pure time-domain measurements with the geometric signal are sensitive to processes at relatively short timescales. The speed of time-series measurement allows for the capture of transient states that describe the time evolution of a system, which complements the information derived from static measurements. Combining the time-resolved DRT with the mapping of equilibrium states can thus provide a more complete perspective on electrochemical behavior.

As described herein, an integrated measurement and analysis technique enables rapid in-situ investigation of electrochemical processes with several advancements to enhance the utility of time-series data. The system-agnostic DRT-DOP model makes the hybrid technique broadly applicable, enabling collection of extensive datasets. Modeling perspectives and algorithms are described to enable new modes of investigation: compared to 1D or 2D analysis with a small number of spectra, multi-dimensional analysis with hundreds of spectra can provide more comprehensive insight with minimal a priori assumptions.

The mapping techniques described herein can be used to identify relationships between discrete processes and state variables despite substantial ambiguity in individual measurements. The methodology described herein may be applicable to various devices to increase the utility of non-invasive in-situ techniques and facilitate deliberate advancements in materials and device design.

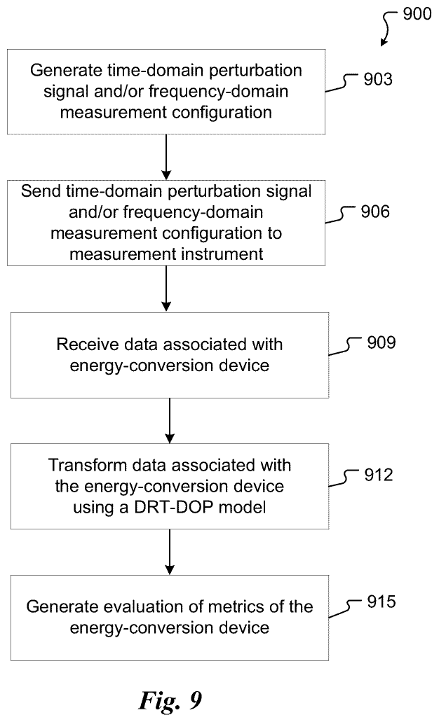

In some implementations, a computing system 109 as described above may be configured to execute an energy-conversion device testing method 900 as described below in relation to the flowchart of FIG. 9. The computing system 109 executing the method may be as described above in relation to FIG. 2 and may be in an environment as described herein in relation to FIG. 1.

As described above, the disclosed systems and methods enable a hybrid technique for rapid electrochemical characterization. A computing system 109 may execute, using a processor 203, a software system to implement a measurement technique, a modeling approach, and/or an application. The technique for electrochemical characterization and analysis as described herein enables, for example, 10-100 times faster measurements, access to transient states, and construction of detailed maps.

At 903, a time-domain perturbation signal and/or a frequency-domain measurement configuration to be used to capture data associated with an energy-conversion device may be generated using the computing system 109. As described above, the energy-conversion device may be one of a battery, a fuel cell, an electrolyzer, a supercapacitor, and a photoelectrochemical device. It should be appreciated that the method 900 may be used to measure metrics associated with any type of energy-conversion device. While particular types of energy-conversion devices may be described, the disclosure should not be considered as being limited to any particular type.

The computing system 109 performing the method 900 may be any type of computing system, such as a personal computer, a tablet device, or a server for example. The method 900 may also be executed on a network of interconnected computing components, leveraging distributed computing frameworks. Such a networked implementation can span from small, local clusters of computers to extensive, geographically distributed cloud computing infrastructures, harnessing collective processing power, storage capacity, and specialized computational resources of multiple devices.

Generating a time-domain perturbation signal may in some implementations comprise generating a current step signal. A current step signal as described herein may be a single current step, while in other implementations the current step signal may be a geometrically shaped current step signal. For example, a current signal may be varied in a controlled, step-wise manner, adhering to a predefined geometric progression.

In some implementations, generating a frequency-domain measurement configuration may comprise generating instructions to control an EIS device to acquire data associated with condition and performance of the energy-conversion device 103.

At 906, the computing system may send the time-domain perturbation signal and/or the frequency-domain measurement configuration to a measurement instrument. To send the time-domain perturbation signal, the computing system 109 may control an EIS device or another device to obtain time-domain data associated with performance and characteristics of an energy-conversion device 103 by applying a current step signal to the battery.

To send the frequency-domain measurement configuration, the method may involve the computing system 109 controlling an EIS device to apply an alternating current signal to the battery.

After sending the time-domain perturbation signal, the computing system 109 may subsequently record the response of the energy-conversion device 103 in the time-domain.

After sending the frequency-domain measurement configuration, the computing system 109 may subsequently measure the resultant response, which may be received by the computing system 109. Data obtained from the EIS measurement may be in the frequency-domain, encompassing a spectrum that reveals the battery's impedance characteristics at various frequencies. This frequency-domain data may provide insights into the battery's internal electrochemical processes, state of health, state of charge, and overall efficiency.

To increase the uniformity of samples in log-timescale space, in some implementations a down-sampling scheme may be applied separately to each step interval (i.e., each interval between consecutive current steps). The first n samples after the current step may be kept at full density (i.e., the sample spacing kept equal to the measurement sample period). The sample spacing may then be increased by a factor of b, and another n samples may be collected. The process may be repeated, increasing the sample spacing by the factor b each time a new batch of n samples is collected, until the step interval ends. The sample spacing may be capped at a maximum interval to avoid excessively large gaps between samples. A digital antialiasing filter may in some implementations be applied to the data prior to down-sampling to reduce the effect of high-frequency noise. For this purpose, an adaptive Gaussian filter may be applied with length scale adjusted to the maximum expected curvature of RC relaxations.

In some implementations, only time-domain data may be received and the method 900 may proceed without receiving frequency-domain data. In other implementations, the measurement device may first collect either frequency- or time-domain data, then may rest for a predetermined period of time, before collecting the other of the frequency- or time-domain data.

In some implementations, the time-domain data and the frequency-domain data may be collected by the same or different measurement instruments 106. For example, the frequency-domain data may be captured by a first measurement instrument 106 performing an electrochemical impedance spectroscopy (EIS) measurement, while the time-domain data may be captured by a second measurement instrument 106 applying a geometric current step signal to the energy-conversion device 103.

In implementations where both frequency-domain data and time-domain data associated with the energy-conversion device 103 are received, the method 900 may include combining the time-domain data and the frequency-domain data. Combining the time-domain data and the frequency-domain data may involve concatenating vectors and/or matrices for each of the time-domain and frequency-domain measurements to obtain a concatenated response matrix.

In some implementations, data vectors for the time- and frequency-domain data may be scaled to obtain consistent results. For example, the data vectors may be scaled based on an estimated polarization resistance of the sample.

The measurements used to capture the data may be performed while the energy-conversion device 103 is in use or in production. For example, in some implementations the method 900 may be used to monitor the health or SOC of the energy-conversion device 103 while the energy-conversion device 103 is being used to provide energy, such as for an electric vehicle, while in other implementations the method 900 may be used to determine whether a newly manufactured energy-conversion device 103 meets certain quality control requirements.

At 912, the computing system 109 may transform the received data associated with the energy-conversion device 103 using a DRT-DOP model.

As described above, the data associated with the energy-conversion device 103 may be frequency-domain and/or time-domain data. Transforming the data may involve transforming one of time-domain data or frequency-domain data using the DRT-DOP model or transforming the combined time-domain data and the frequency-domain data using the DRT-DOP model.

At 915, the computing system 109 may generate an electrochemical impedance spectrum of the energy-conversion device 103 based on the DRT-DOP model. The one or more metrics may include one or more of a distribution of relaxation times and a distribution of phasances. In some implementations, generating an electrochemical impedance spectrum of the energy-conversion device 103 may comprise generating an electrochemical mapping of the energy-conversion device 103 using one or more of a surface regression methodology, a surface filtering, a surface structure, a sheet probability function, a sheet-tracing algorithm, a GP-ZARC model, or other methodology.

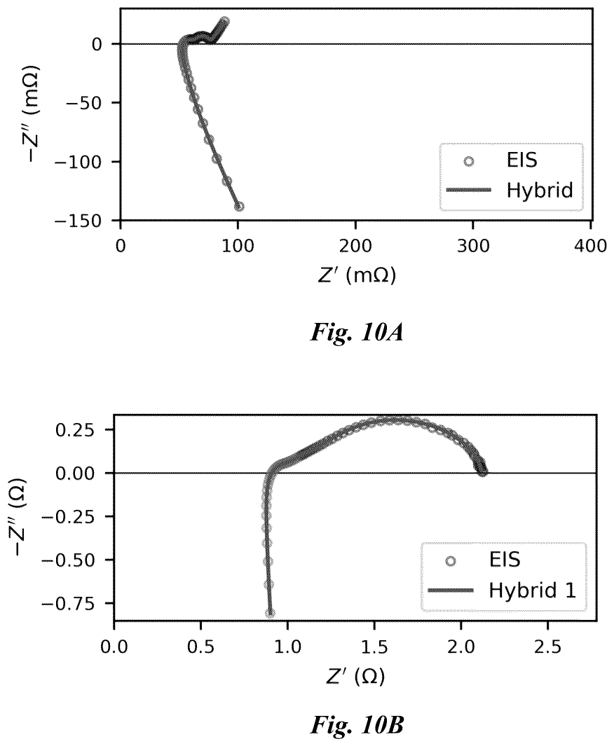

FIGS. 10A and 10B display the results of the hybrid measurement in comparison to the conventional EIS measurement. FIG. 10A illustrates an impedance spectrum captured using the hybrid methods described herein for an LIB (represented by the solid line) as compared to a conventional EIS spectrum for the LIB (represented by the circles). FIG. 10B illustrates an impedance spectrum captured using the hybrid methods described herein for a PCEC (represented by a solid line) as compared to a conventional EIS spectrum for the PCEC (represented by circles). As should be appreciated, the hybrid methodology described herein provides results closely aligned with conventional EIS DRT over the entire timescale range.

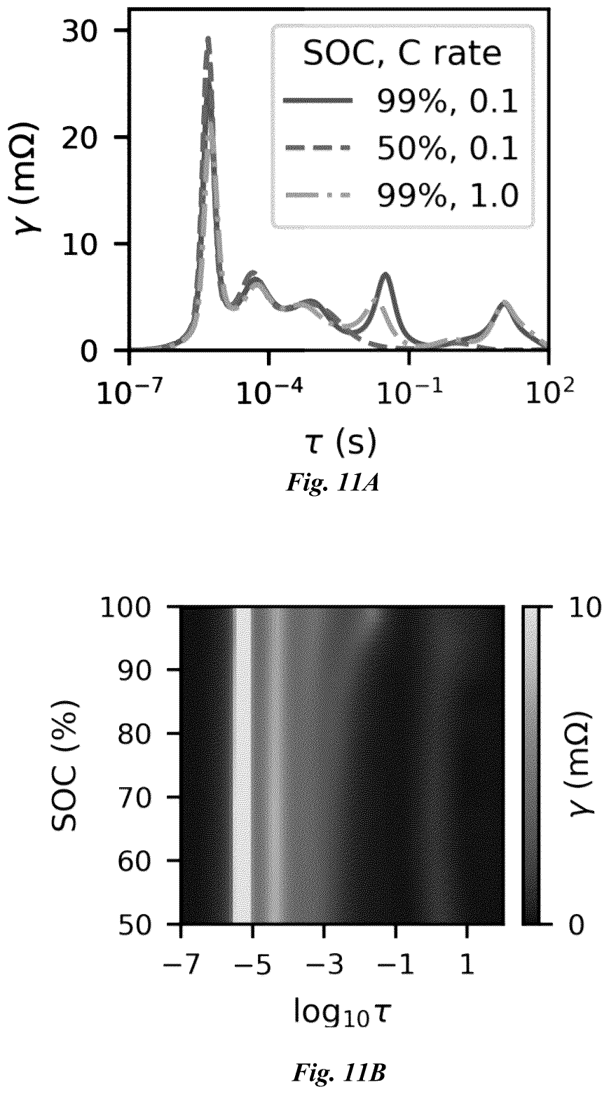

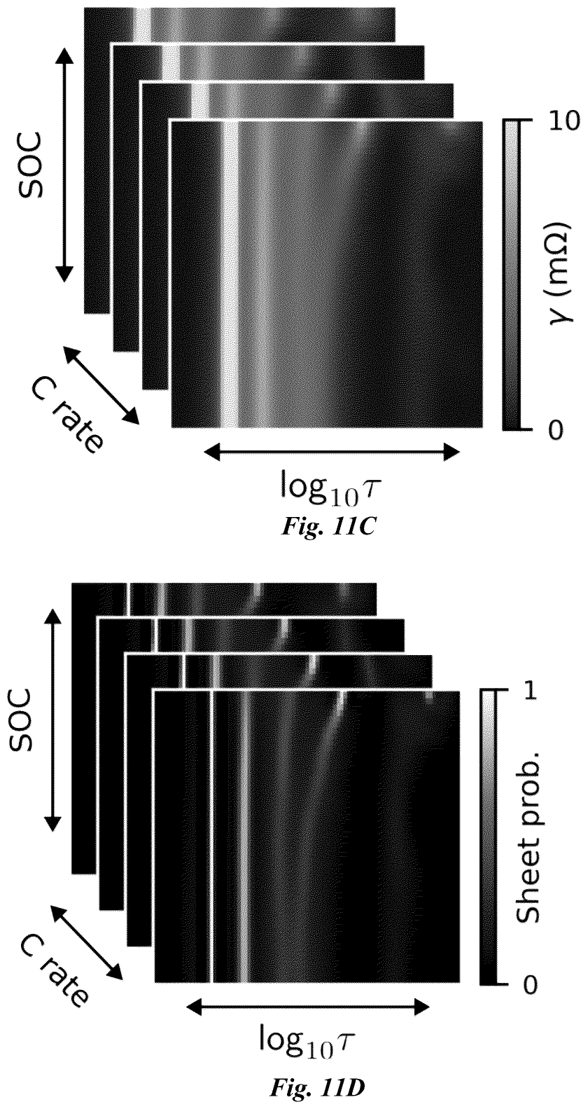

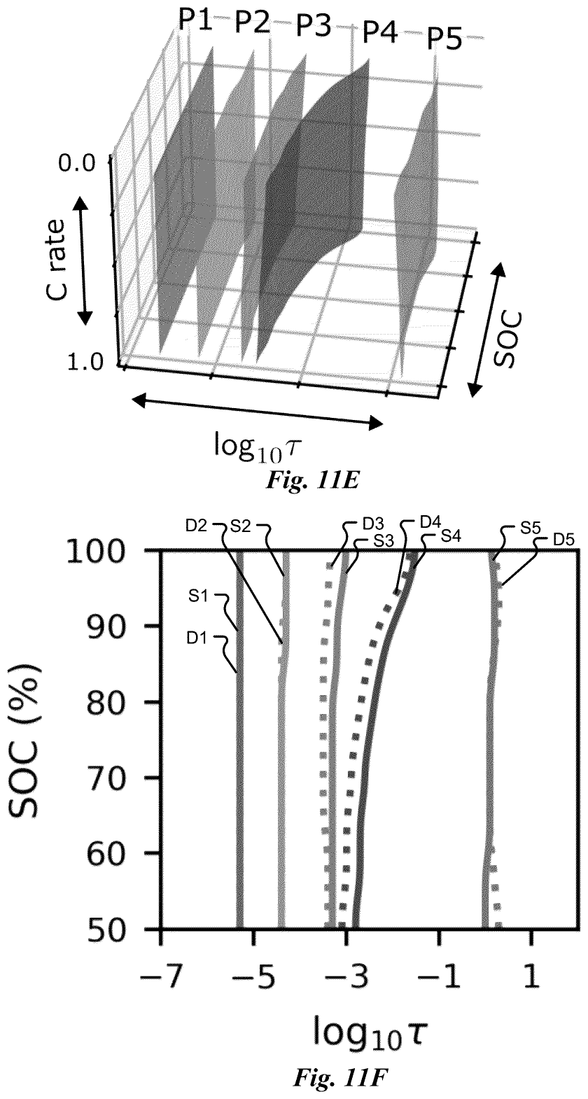

FIGS. 11A-F illustrate a process of mapping impedance of an energy-conversion device in accordance with one or more of the embodiments described herein. The energy-conversion device used to create the data illustrated in FIGS. 11A-F is an LIB.

In FIG. 11A, it can be appreciated that the one-dimensional DRT varies with both state of charge SOC and C rate. The C rate of an energy-conversion device may be described as a measurement of current at which a battery is charged and/or discharged. The solid, darker, solid line represents the LIB at a 99% SOC and a C rate of 0.1. The middle dark dashed line represents the LIB at a 50% SOC and a C rate of 0.1. The lighter, dash-dot-dash line represents the LIB at a 99% SOC and a C rate of 1.0. The vertical axis represents DRT (“7”) measured in milliohms (mΩ) and the horizontal axis represents time-scales (“τ”).

While individual hybrid measurements can be fitted to obtain a one-dimensional (1D) DRT at different SOCs and C rates, it may be difficult to determine how SOC and C rate interact to influence the DRT of an energy-conversion device. For this reason, the hybrid spectra from a single discharge cycle can be aggregated to form a two-dimensional DRT surface extending along the SOC dimension to gain a detailed view of how SOC influences the DRT of the energy conversion device. FIG. 11B illustrates spectra at different SOCs from a single discharge test at 0.7 C aggregated to produce a two-dimensional DRT surface.

This concept can be extended by stacking two-dimensional surfaces from different charge cycles, effectively adding a C-rate dimension to the two-dimensional DRT surface to form a three-dimensional DRT hypersurface in the ln τ-SOC-C-rate space. FIG. 1 IC illustrates adding the dimension of C rate to the two-dimensional DRT surface to produce a three-dimensional hypersurface by the stacking of two-dimensional surfaces from different discharge tests.

A probabilistic approach may be taken to robustly identify sheets in the DRT hypersurface. A semi-quantitative sheet probability function may be defined that indicates the relative likelihood of the presence of a sheet at any point in the ln τ-ψ space, as illustrated in FIG. 11D, where ψ represents a space of state variables, such as temperature and local chemistry, denoted as ψ=[ψ₁, ψ₂, . . . , ψ_{N}], and where each ψₙ indicates a variable of interest, such as SOC and C rate. The sheet probability function highlights probable sheet locations by considering the topography and uncertainty of the DRT hypersurface. Next, an algorithm may be defined to identify a discrete set of sheets underlying the continuous sheet probability surface by tracing contours of maximum plausibility.

As illustrated in FIG. 11E, five distinct sheets, labeled as P1-P5, may be found in the hypersurface in three-dimensions. For visualization purposes, fixed-C rate two-dimensional sections of the space are taken at 0.1 C and 1.0 C, slicing a curve from each sheet as illustrated in FIG. 11F.

The dotted lines D1-D5 of FIG. 11F represent a two-dimensional section of the space for each sheet P1-P5, respectively, taken at a C rate of 0.1. The solid lines S1-S5 represent a two-dimensional section of the space for each sheet P1-P5, respectively, taken at a C rate of 1.0. As can be realized from the graph of FIG. 11F, P3 and P4 shift to shorter timescales as the C rate increases and/or SOC decreases (as indicated by the separation of D3 from S3 and D4 from S4), while the positions of P1, P2, and P5 are nearly constant throughout the changing C rate and SOC (as indicated by the overlap of S1 with D1, of S2 with D2, and S5 with D5).

Any of the steps, functions, and operations discussed herein can be performed continuously and automatically. A number of variations and modifications of the disclosure can be used. It would be possible to provide for some features of the disclosure without providing others.

References in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases may not necessarily refer to the same embodiment. Further, when a particular feature, structure, or characteristic is described in conjunction with one embodiment, it is submitted that the description of such feature, structure, or characteristic may apply to any other embodiment unless so stated and/or except as will be readily apparent to one skilled in the art from the description. The present disclosure, in various embodiments, configurations, and aspects, includes components, methods, processes, systems and/or apparatus substantially as depicted and described herein, including various embodiments, sub combinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

The present disclosure encompasses methods with fewer than all of the steps identified in the description. The present disclosure also encompasses methods that comprise one or more steps from one method described herein, and one or more steps from another method described herein. Any correlation described herein may be or comprise a registration or any other correlation.

Embodiments of the present disclosure include a system for mapping impedance of an energy-conversion device, the system comprising: a processor; and a memory device coupled with the processor, wherein the memory device comprises data stored thereon that, when processed by the processor, enables the processor to: receive raw time-domain data associated with the energy-conversion device; performing an electrochemical impedance spectroscopy (EIS) measurement to generate raw frequency-domain data; transform the raw time-domain and frequency-domain data using a distribution of relaxation times and distribution of phasances (DRT-DOP) model; and generate, based on the DRT-DOP model, an electrochemical impedance spectrum of the energy-conversion device.

Aspects of the above system include wherein receiving the raw time-domain data comprises applying a geometric step signal to the energy-conversion device before or after performing the EIS measurement.

Aspects of the above system include wherein the data further enables the processor to combine the raw time-domain data and the raw frequency-domain data.

Aspects of the above system include wherein the data further enables the processor to calculate a frequency-resolved impedance spectrum directly from the distribution of relaxation times or the DRT-DOP model.

Aspects of the above system include wherein the data further enables the processor to output the electrochemical impedance spectrum at different timescales.

Aspects of the above system include wherein the raw time-domain data is measured in a series of steps at geometrically increasing intervals.

Aspects of the above system include wherein the data further enables the processor to perform anti-alias filtering of the raw time-domain data.

Aspects of the above system include wherein the electrochemical impedance spectrum comprises multi-dimensional electrochemical map of the energy-conversion device.

Aspects of the above system include wherein receiving the raw time-domain data comprises using a potentiostat to apply a current signal to the energy-conversion device.

Aspects of the above system include wherein receiving the raw time-domain data comprises using a potentiostat to apply a series of current signals to the energy-conversion device.

Aspects of the above system include wherein receiving the raw time-domain data comprises detecting a response of the energy-conversion device to the series of current or voltage signals.

Aspects of the above system include wherein the energy-conversion device is one of a battery, a fuel cell, an electrolyzer, a supercapacitor, and a photoelectrochemical device.

Aspects of the above system include wherein the DRT-DOP model comprises a combination of an impedance measured using DRT and an impedance measured using DOP.

Embodiments of the present disclosure also include a computing device for mapping impedance of an energy-conversion device, the computing device comprising a processor to perform: receiving raw time-domain data associated with an energy-conversion device; performing an electrochemical impedance spectroscopy (EIS) measurement to generate raw frequency-domain data; transforming the raw time-domain and frequency-domain data using a distribution of relaxation times and distribution of phasances (DRT-DOP) model; and generating, based on the DRT-DOP model, an electrochemical impedance spectrum of the energy-conversion device.

Aspects of the above computing device include wherein receiving the raw time-domain data comprises applying a geometric step signal to the energy-conversion device before or after performing the EIS measurement.

Aspects of the above computing device include wherein the data further enables the processor to combine the raw time-domain data and the raw frequency-domain data.

Aspects of the above computing device include wherein the data further enables the processor to calculate a frequency-resolved impedance spectrum directly from the distribution of relaxation times or the DRT-DOP model.

Aspects of the above computing device include wherein the data further enables the processor to output the electrochemical impedance spectrum at different timescales.

Aspects of the above computing device include wherein the raw time-domain data is measured in a series of steps at geometrically increasing intervals.

Embodiments of the present disclosure also include a method of mapping impedance of an energy-conversion device, the method comprising: receiving raw time-domain data associated with the energy-conversion device; performing an electrochemical impedance spectroscopy (EIS) measurement to generate raw frequency-domain data; transforming the raw time-domain and frequency-domain data using a distribution of relaxation times and distribution of phasances (DRT-DOP) model; and generating, based on the DRT-DOP model, an electrochemical impedance spectrum of the energy-conversion device.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

It is to be appreciated that any feature described herein can be claimed in combination with any other feature(s) as described herein, regardless of whether the features come from the same described embodiment.

What is claimed is:

1. A system for mapping impedance of an energy-conversion device, the system comprising:
a processor; and
a memory device coupled with the processor, wherein the memory device comprises data stored thereon that, when processed by the processor, enables the processor to:
receive raw time-domain data associated with the energy-conversion device;
performing an electrochemical impedance spectroscopy (EIS) measurement to generate raw frequency-domain data;
transform the raw time-domain and frequency-domain data using a distribution of relaxation times and distribution of phasances (DRT-DOP) model; and
generate, based on the DRT-DOP model, an electrochemical impedance spectrum of the energy-conversion device.

2. The system of claim 1, wherein receiving the raw time-domain data comprises applying a geometric step signal to the energy-conversion device before or after performing the EIS measurement.

3. The system of claim 1, wherein the data further enables the processor to combine the raw time-domain data and the raw frequency-domain data.

4. The system of claim 1, wherein the data further enables the processor to calculate a frequency-resolved impedance spectrum directly from the distribution of relaxation times or the DRT-DOP model.

5. The system of claim 1, wherein the data further enables the processor to output the electrochemical impedance spectrum at different timescales.

6. The system of claim 1, wherein the raw time-domain data is measured in a series of steps at geometrically increasing intervals.

7. The system of claim 9, wherein the data further enables the processor to perform anti-alias filtering of the raw time-domain data.

8. The system of claim 1, wherein the electrochemical impedance spectrum comprises multi-dimensional electrochemical map of the energy-conversion device.

9. The system of claim 1, wherein receiving the raw time-domain data comprises using a potentiostat to apply a current signal to the energy-conversion device.

10. The system of claim 1, wherein receiving the raw time-domain data comprises using a potentiostat to apply a series of current signals to the energy-conversion device.

11. The system of claim 10, wherein receiving the raw time-domain data comprises detecting a response of the energy-conversion device to the series of current or voltage signals.

12. The system of claim 1, wherein the energy-conversion device is one of a battery, a fuel cell, an electrolyzer, a supercapacitor, and a photoelectrochemical device.

13. The system of claim 1, wherein the DRT-DOP model comprises a combination of an impedance measured using DRT and an impedance measured using DOP.

14. A computing device for mapping impedance of an energy-conversion device, the computing device comprising a processor to perform:
receiving raw time-domain data associated with an energy-conversion device;
performing an electrochemical impedance spectroscopy (EIS) measurement to generate raw frequency-domain data;
transforming the raw time-domain and frequency-domain data using a distribution of relaxation times and distribution of phasances (DRT-DOP) model; and
generating, based on the DRT-DOP model, an electrochemical impedance spectrum of the energy-conversion device.

15. The computing device of claim 14, wherein receiving the raw time-domain data comprises applying a geometric step signal to the energy-conversion device before or after performing the EIS measurement.

16. The computing device of claim 14, wherein the data further enables the processor to combine the raw time-domain data and the raw frequency-domain data.

17. The computing device of claim 14, wherein the data further enables the processor to calculate a frequency-resolved impedance spectrum directly from the distribution of relaxation times or the DRT-DOP model.

18. The computing device of claim 14, wherein the data further enables the processor to output the electrochemical impedance spectrum at different timescales.

19. The computing device of claim 14, wherein the raw time-domain data is measured in a series of steps at geometrically increasing intervals.

20. A method of mapping impedance of an energy-conversion device, the method comprising:
receiving raw time-domain data associated with the energy-conversion device;
performing an electrochemical impedance spectroscopy (EIS) measurement to generate raw frequency-domain data;
transforming the raw time-domain and frequency-domain data using a distribution of relaxation times and distribution of phasances (DRT-DOP) model; and
generating, based on the DRT-DOP model, an electrochemical impedance spectrum of the energy-conversion device.
